(19) United States
(12) Patent Application Publication
(10) Pub. No.: US 2013/0037092 A1
(43) Pub. Date: Feb. 14, 2013

(54) FERROELECTRIC DIODE AND PHOTOVOLTAIC DEVICES AND METHODS

(71) Applicants: Sang-Wook Cheong, Chatham, NJ (US); Taekjib Choi, Seoul (KR); Seongsu Lee, Daejeon (KR)

(72) Inventors: Sang-Wook Cheong, Chatham, NJ (US); Taekjib Choi, Seoul (KR); Seongsu Lee, Daejeon (KR)

(73) Assignee: RUTGERS, THE STATE UNIVERSITY OF NEW JERSEY, New Brunswick, NJ (US)

(21) Appl. No.: 13/578,544

(22) PCT Filed: Feb. 11, 2011
(86) PCT No.: PCT/US11/24532

§ 371 Date: Oct. 16, 2012

Related U.S. Application Data
(60) Provisional application No. 61/304,071, filed on Feb. 12, 2010.

(51) Int. Cl. H01L 29/82; H01L 31/0224

(52) U.S. Cl. 136/254; 257/421; 257/E29.323

(57) ABSTRACT

Provided are diodes and photovoltaic devices incorporating a single-crystalline ferroelectric or pyroelectric with remnant electric polarization sandwiched with transparent or semitransparent electrodes.

### CROSS REFERENCE TO RELATED APPLICATIONS

This application claims priority from U.S. Provisional Patent Application No. 61/304,071 filed on Feb. 12, 2010 by Cheong titled “FERROELECTRIC DIODE AND PHOTOVOLTAIC DEVICES AND METHODS,” which is incorporated herein by reference in its entirety.

### FIELD OF THE INVENTION

This invention generally relates to diodes, photovoltaic devices, and methods for the production thereof and uses therefore, and more particularly, to diodes and photovoltaic devices comprising a single-crystalline ferroelectric or pyroelectric with remnant electric polarization sandwiched with transparent or semitransparent electrodes.

### BACKGROUND OF THE INVENTION

Generally, ferroelectrics and pyroelectrics are highly insulating. In fact, any conduction, i.e., loss term, in ferroelectrics and pyroelectrics is considered detrimental for most technological applications. Thus, use of ferroelectrics or pyroelectrics in diodes or photovoltaic devices has been contraindicated.

However, conduction in ferroelectrics and pyroelectrics associated with new phenomena, specifically rectification of electric transport current and visible-light-range photovoltaic effects has recently been discovered. Accordingly, there exists a need for electronic components that make advantageous use of these newly-discovered properties of single-crystalline ferroelectrics or pyroelectrics.

### SUMMARY OF THE INVENTION

An aspect of the present invention provides a diode including a single-crystalline ferroelectric having remnant electrical polarization sandwiched with semitransparent electrodes. In a further aspect of the invention, the single-crystalline ferroelectric is BiFeO₃ (“BFO”) having a thickness of 70 ma-90 ma, and the electrodes are Au or Ag.

Another aspect of the present invention provides a plurality of the above diodes in an electronic memory device, the diodes being operatively connected in an electronic memory network.

Another aspect of the present invention provides a photovoltaic device including a single-crystalline ferroelectric having remnant electrical polarization sandwiched with semitransparent electrodes. In a further aspect of the invention, the single-crystalline ferroelectric is BiFeO₃ (“BFO”) having a thickness of 70 ma-90 ma, and the electrodes are Au or Ag.

Another aspect of the present invention provides a solar cell which includes a plurality of the above photovoltaic device, the photovoltaic devices being interconnected either serially or in parallel.

### BRIEF DESCRIPTION OF THE DRAWINGS

FIG. 1A depicts the observed diode effect in the BFO1 specimen, in accordance with an embodiment of the present invention;

FIG. 1B depicts the observed diode effect in the BFO2 specimen, in accordance with an embodiment of the present invention;

FIG. 2A depicts aspects of the observed switchable diode effect with flipping ferroelectric polarization, in accordance with an embodiment of the present invention;

FIG. 2B depicts aspects of the observed switchable diode effect with flipping ferroelectric polarization, in accordance with an embodiment of the present invention;

FIG. 2CA depicts aspects of the observed switchable diode effect with flipping ferroelectric polarization, in accordance with an embodiment of the present invention;

FIG. 3A depicts the zero-bias photocurrent density as a function of time with green light (˜=532 nm) on or off, in accordance with an embodiment of the present invention;

FIG. 3B depicts the zero-bias photocurrent density as a function of time with red light (˜=650 nm) on or off, in accordance with an embodiment of the present invention;

FIG. 4 depicts the variation of photocurrent with sample rotation under illumination with a linearly-polarized light, in accordance with an embodiment of the present invention;

FIG. 5A depicts typical P-E hysteresis loops of an Au/BFO (90 μm)/Au structure at 10K, in accordance with an embodiment of the present invention;

FIG. 5B depicts the topography of a BFO crystal, in accordance with an embodiment of the present invention;

FIG. 5C depicts an out-of-plane PFM image of a 10×10 μm² syrface area of a 20-μm-thick BFO crystal at room temperature, obtained after applying DC+−40 V (E=20 kV/cm) to different areas: the subsequently-scanned areas were 8×8 μm² (+40 V), 4×4 μm² (−40V), and 2×2 μm² (+40 V), the PFM image demonstrates homogeneous polarization switching by +−40 V, in accordance with an embodiment of the present invention;

FIG. 6A depicts typical J-E characteristics of an Au/BFO/Au structure (“BFO1”, hereinbelow) at 300 K, in accordance with an embodiment of the present invention;

FIG. 6B depicts a plot of leakage current for the SCLC conduction mechanism;

FIG. 6C depicts a plot of leakage current for the Schottky emission conduction mechanism;

FIG. 6D depicts a plot of leakage current for the Poole-Frenkel emission conduction mechanism;

FIG. 7 depicts rectification switching in symmetric Ag/BFO/Ag and Au/BFO/Au structures (“BFO3”, hereinbelow) associated with ferroelectric polarization reversal induced by large voltage pulses (100 pulses with maximum voltage of +−150 V (E of +−17 kV/cm) and pulse duration of 0.01 s, in accordance with an embodiment of the present invention;

FIG. 8 is a schematic diagram depicting a memory cell, in accordance with an embodiment of the present invention; and,

FIG. 9 is a schematic diagram depicting a solar cell, in accordance with an embodiment of the present invention.

### DETAILED DESCRIPTION

The present invention is drawn to diodes, photovoltaic devices, and methods for the production thereof and uses therefore. The diode and photovoltaic devices comprise a single-crystalline ferroelectric or pyroelectric with remnant electric polarization sandwiched with transparent or semitransparent electrodes.

Although ferroelectrics and pyroelectrics are highly insulating and any conduction (i.e. loss term) in ferroelectrics and pyroelectrics is considered detrimental for most technological applications, it has been discovered that the conduction in ferroelectrics and pyroelectrics is associated with new phenomena, specifically rectification of electric transport current and visible-light-range photovoltaic effects. The rectification direction and the direction of photovoltaic current are directly related with the direction of electric polarization of ferroelectrics and pyroelectrics.

Thus, these new phenomena can be utilized for many practical applications including new memory devices and new solar cells advantageously based on diodes and photovoltaic devices incorporating a single crystalline ferroelectric or pyroelectric as described herein, having increased power conversion efficiency. This increased power efficiency advantageously provides for a better solar energy harvest. Compared with solar cells based on p-n junctions, ferroelectric photo-voltaic cells can be cheaper and more efficient. Memory devices utilizing ferroelectric diode and photovoltaic effects can have much higher memory density. Optical sensors using ferroelectric diode and photovoltaic effects may have more sensitivity or larger dynamic range. Moreover, the phenomenon of a significant electric conduction with illumination can be utilized for applications with combined photovoltaic and diode effects; for example, light sensor (photo-diode), optical non-volatile memory and optical MEMS (micro-electro-mechanical system) applications.

Photocurrents can be induced by high-energy (larger than optical gap; often UV range) light illumination, and associated photovoltaic effects have been known in standard ferroelectrics. When a ferroelectric in an open circuit is illuminated by UV light, a high photovoltaic (much larger than the band gap) can develop in the direction of electric polarization. The magnitude of this photovoltaic is directly proportional to the crystal length in the polarization direction. In addition, a steady-state photovoltaic current can be generated in the direction of electric polarization when a ferroelectric under continuous light illumination forms a closed circuit.

The present invention advantageously provides a diode including a single-crystalline ferroelectric having remnant electrical polarization sandwiched with semitransparent electrodes. In various embodiments of the invention, the single-crystalline ferroelectric is BiFeO₃ (“BFO”) has a thickness of 70 ma-90 ma, and the electrodes are Au or Ag. In particular, thicknesses of ˜70 ma, ˜80 ma, and ˜90 ma have been tested, although other thicknesses in the 10 ma-90 ma range are also contemplated.

The present invention also advantageously provides for these diodes to be used in an electronic memory device, the diodes being operatively connected in an electronic memory network.

The present invention also advantageously provides a photovoltaic device including a single-crystalline ferroelectric having remnant electrical polarization sandwiched with semitransparent electrodes. Similarly to the above diodes, the single-crystalline ferroelectric is BiFeO₃ (“BFO”) having a thickness of 70 ma-90 ma, and the electrodes are Au or Ag.

The present invention also provides a solar cell which includes a plurality of the above photovoltaic devices interconnected either serially or in parallel.

Switchable Ferroelectric Diode and Photovoltaic effect in BiFeO3: Diode effect, i.e., a uni-directional electric current flow, is important for modern electronics. It usually occurs in asymmetric interfaces such as p-n junctions or metal-semiconductor interfaces with Schottky barriers. Herein is reported the discovery of a diode effect associated with the direction of bulk electric polarization in BiFeO3, which is a ferroelectric with a relatively small optical gap edge of ˜2.2 eV. It was found that bulk electric conduction in ferroelectric monodomain BiFeO3 crystals is highly non-linear, and uni-directional. Remarkably, this diode effect switches its direction when the electric polarization is flipped by an external voltage. Associated with the diode effect, a large directional photocurrent at zero bias can be induced by visible light in ferroelectric monodomain BiFeO˜—i.e., a significant photovoltaic effect is observed. These unprecedented diode-like and photovoltaic effects in BiFeO˜ allow for advances in the fundamental understanding of charge conduction mechanism in leaky ferroelectrics, as well as in the design of new switchable devices combining ferroelectric, electronic, and optical functionalities.

Ferroelectrics consist of ferroelectric domains with broken space inversion symmetry. The domains are distinguished by the direction of the electric polarization which can be switched with an external electric field. Ferroelectrics are typically highly insulating due to large band gaps, and any current leakage in ferroelectrics has been considered as a serious problem that deteriorates their functionalities. The relationship between electronic transport characteristics and ferroelectric polarization has been little studied. This is partially due to complexity associated with ferroelectric domains. In addition, leakage often occurs through extended crystallographic defects such as grain boundaries or ferroelectric domain boundaries, so the true bulk leakage conduction may not be always dominant.

On the other hand, bulk photocurrent can be induced by high-energy—larger than optical gap; often UV range—light illumination even in good insulators, and directional photocurrent without external bias, i.e., a photovoltaic (PV) effect, has been studied in ferroelectrics. When a ferroelectric in an open circuit is illuminated by, e.g., UV light, a high photovoltage, much larger than the band gap, has been observed in the direction of the electric polarization. The magnitude of this photovoltage is directly proportional to the crystal length in the polarization direction. In addition, a steady-state photocurrent can be generated in the direction of electric polarization when a ferroelectric under continuous light illumination forms a closed circuit. This PV effect in ferroelectrics is distinctly different from the typical PV effect in semiconductor p-n junctions, and was investigated, for example, in Pb-based ferroelectric oxides and LiNbO3. However, the observed photocurrent density turns out to be minuscule—on the order of a few nano-Amperes/cmz^{z}, mainly due to poor bulk DC conduction of the ferroelectrics. Utilization of small optical-gap ferroelectrics with good carrier transport properties and large absorption of visible light extending into the red range is therefore a promising route towards novel opto-electronic applications. It may, for example, lead to increased power conversion efficiency in solar energy applications, and clearly deserves close attention. Such a need is further emphasized by the highly controversial origin of the PV effect in ferroelectfics: it was discussed in terms of extrinsic effects such as excitation of electrons from asymmetric impurity potentials, interracial effects due to polarization-dependent band bending at metal-ferroelectric interfaces, or intrinsic effects such as asymmetric induced polarization through non-linear optical processes.

Ferroelectric BiFeO₃ (“BFO”) contains transition metal ions with unpaired d electrons. The presence of the d electrons can result in a relatively small optical gap, and give rise to a high concentration of charged impurities/defects. Current extensive studies of DC transport properties of ferroelectric monodomain BFO crystals have shown: 1.) there exists a significant DC current in a single-ferroelectric-domain BFO crystal; 2.) the magnitude of the DC current strongly depends upon the electric polarization direction even if electrode structure is symmetric, i.e. there exists a strong diode-like effect; 3.) the direction of this diode-like effect is reproducibly switchable by large external electric fields; and, 4.) a significant zero-bias PV effect exists when the crystal is illuminated with visible light. The maximum closed-circuit photocurrent density reaches 7.35/zA/cm² for sub-20 mW/cm² power density of visible light. It is noteworthy that prior to the current studies, any diode-like effect of DC conduction has been reported to be absent in (111) BFO films.

BFO becomes ferroelectric at Tc˜1,100 K, below which BFO exhibits a rhombohedral Ric structure with a perovskite pseudocubic unit cell (a˜3.96 A,)c˜89.4°) elongated along the [111] direction that coincides with the electric polarization vector P. Each of our BFO crystals turns out to contain one single ferroelectric domain. Reproducible electronic transport properties were observed in a number of thin plate-like BFO crystals placed between symmetric electrodes, although only three prototypical plate-like specimens are discussed herein:

BFO1: ˜70/ma thickness, −2×2 mm² in-plane dimension, and −0.6 ram-diameter circular thick Au electrodes

BFO2: ˜80/ma thickness, −2.5×2.5 mm² in-plane dimension, and N1.6×1 mm^{z} semitransparent Au electrodes, and

BFO3: ˜90/ma thickness, −1×2 mm² in-plane dimension, and −0.6 mm-diameter circular thick Ag or Au electrodes.

The BFO plates were normal to a principal axis of the pseudocubic cell, and the “in-plane or our-of-plane” component of the polarization was defined with respect to the plate surface.

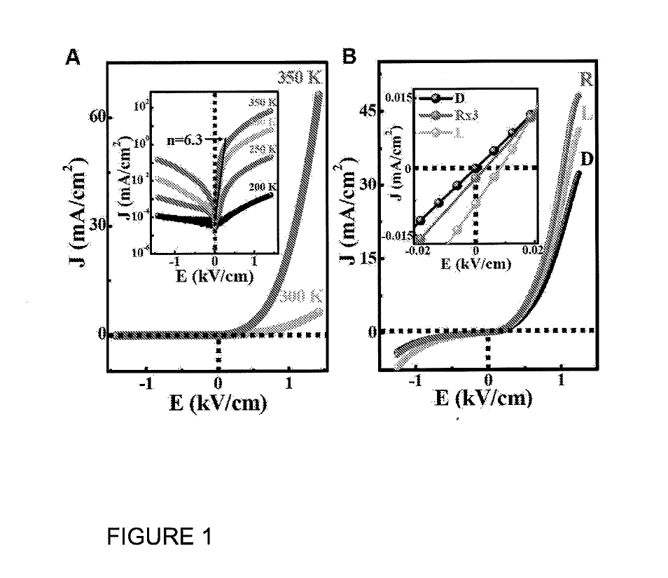

FIG. 1A depicts the observed diode effect in the BFO1 specimen, and FIG. 1B depicts the observed diode effect in the BFO2 specimen.

As observed in FIG. 1A, the J(E) curve of a symmetric Au/BFO1/Au structure in the dark at 300 K and 350 K, a significant diode-like effect is evident. The inset shows semilog-scale J(E) curves at various temperatures. All J(E) measurements were performed by sweeping the voltage from the positive maximum to the negative maximum in vacuum at 200-350 K. Note that the applied electric fields are far below the coercive field for polarization switching.

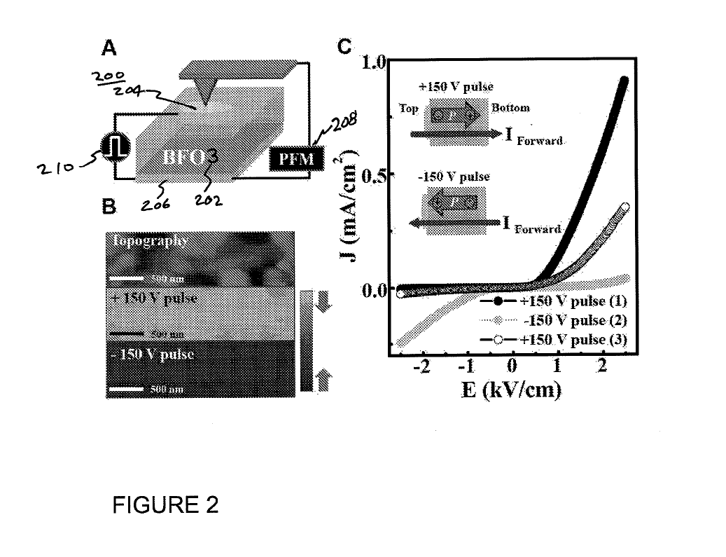

FIGS. 2A, 2B and 2C depict various aspects of the observed switchable diode effect with flipping ferroelectric polarization in an embodiment of the present invention. FIG. 2A shows a sketch of the set-up 200 for the simultaneous PFM 208 and J(E) 210 measurements on an exemplary Ag/BFO3/Ag diode, including the Ag conductor sandwich 204, 206 and the BFO3 layer 202. One-hundred electric pulses with +150 V (E=17 kVtcm) and the 0.01s duration were used to flip electric polarization, J(E) was measured up to E=2.5 kV/cm, and AC voltage of 1 V˜ and 17 kHz was used for PFM. FIG. 2B shows a topography image and out-of-plane PFM images after +150 V pulses. The PFM signal is color-scaled. These images show that +(−)150 V pulses induced a homogeneous state with downward (upward) out-of-plane polarization. Fig. C shows J(E) curves of BFO3 after +150 V, −150 V and +150 V pulses, in sequence. The diode forward-reverse directions switched when the direction of out-of-plane polarization was reversed by −I-150 V pulses. The diode forward direction turned out to be the same with the direction of electric pulses used for polarization flipping.

FIG. 2B depicts the J(E) curve of the BFO2 sample in the dark, and with green-light illumination on right (R) or left (L) semitransparent Au electrodes. Current for either E direction (except very near E=0) increases with illumination on either side. The inset of FIG. 2B shows an expanded view of the J(E) curves near zero bias field (E=0). Zero-bias current flows along the reverse direction with either-direction illumination: L-side illumination works better than R-side illumination for this particular set-up, and the x- and y-axes for the R-side illumination are expanded by a factor 3 to show clearly the presence of the reverse-direction current for zero bias.

All investigated specimens exhibited significant currents that are non-linear with applied electric field, E, and also depend strongly on the direction of E. It was noted that the magnitude of E here was much less than ferroelectric coercivity, so polarization switching does not occur during the E sweep for current density, J, vs. E curves. FIG. 1A shows linear-scale J(E) curves of BFO1 at 300 K and 350 K, which exhibited a clear diode-like behavior. For the typical p-n junction diodes, the forward current density follows an exponential relationship with applied voltage given by Jocexp(qV/nk˜T), where q is the electron charge, k˜ is the Boltzmann constant, T is temperature, and n is a constant called the ideality factor. In the range of 0.05-0.15 kV/cm forward bias, n is 6.3 (4.7) at 300 K (350 K). This large ideality factor, much larger than the ideal value of 1 in semiconductor p-n junctions, has been observed in perovskite-based oxide p-n junctions, where charge trapping at defects in the bulk seems important for transport properties (18). It was also found that J increases drastically with increasing temperature from 200 K to 350 K as evident in the semi-log plot of J(E) curves in the inset of FIG. 1A. In addition, the asymmetry in the J(E) curve also increases remarkably with increasing T. The rectification ratios for E=1.3 kV/cm at 200, 250, 300, and 350 K are 13, 159, 488, and 495, respectively.

Remarkably, the diode forward-reverse directions switched when ferroelectric polarization was uniformly reversed by large electric voltage pulses. When +150 V (E of +17 kV/cm) pulses were applied to the top electrode of BFO3 shown in the FIG. 2A, the ferroelectric polarization pointed down, as confirmed by PFM (FIG. 2B). The electric current through the specimen was then large when the current direction was also downward, i.e., the diode forward direction is from top to bottom, and along the polarization direction (FIG. 2C). When −150 V pulses were applied, ferroelectric polarization switched to the upward direction, and the diode forward direction became from bottom to top, still along the polarization direction. Application of +150 V pulses brought back the original configuration. Therefore, the diode directions switched whenever ferroelectric polarization was reversed by external pulses, and the diode forward direction was always along the ferroelectric polarization direction (FIG. 2C). Note that only the out-of-plane component of ferroelectric polarization was considered because of the plate-like geometry of the Ag/BFO3/Ag structure. Also note that even though the simultaneous J(E) and PFM experiments with electric pulses were performed only on BFO3, the switchable J(E) curves were observed in all specimens investigated. Although the reason why no diode effect was observed in ferroelectric monodomain (111) BFO films still needs to be clarified, it is generally known that (111) films are not of a high quality and are highly conducting, and therefore extrinsic effects on transport properties, such as conduction through grain/domain boundaries or pin holes, have to be considered.

The observed diode-like behavior of DC conduction implies a possibility of zero-bias PV effect in BFO. Since the optical gap edge of BFO is reported to be −2.2 eV, visible light is expected to induce significant photocurrent. Indeed, a significant PV effect in BFO with semitransparent Au electrodes illuminated with visible light (˜=532 nm green, and) ˜=630 nm red light) with the total power density less than 20 mW/cm² was discovered.

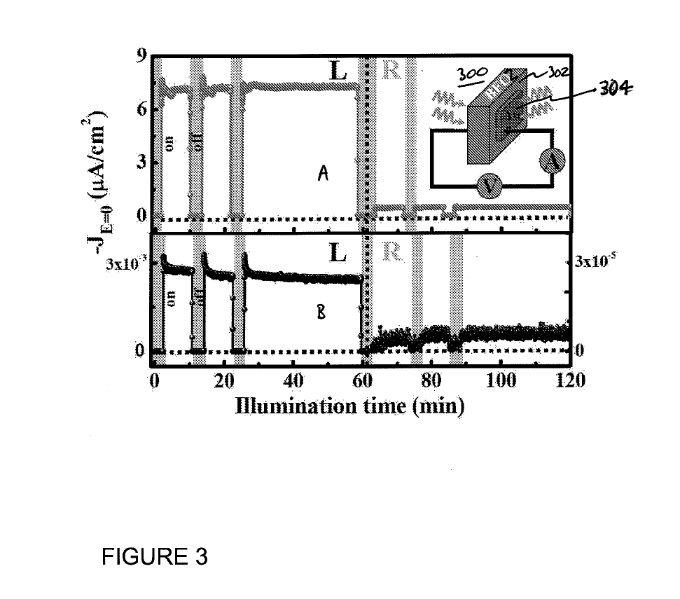

FIG. 1B depicts the J(E) curves of BFO2 with symmetric Au electrodes in green light as well as in the dark. Green light illuminated either left (L) or right (R) semitransparent Au electrodes of BFO2, as shown by the experimental schematic in the inset of FIG. 3. Evidently, illumination on either side induces the increase of conductance with both forward and reverse bias electric fields. The direction of photocurrent depends on the direction of the external bias. However, for zero bias, the photocurrent does exist and is always negative, independent from the illumination direction-negative 0.13 (0.013)/˜k, corresponding to reverse-bias-direction 8.219 (0.849) pA/cm² for the BFO2 configuration with the left (right)-side illumination, as shown by the inset of FIG. 1B. This bulk photocurrent in absence of an external bias indicates that charge carriers induced by light illumination move preferentially along one direction, i.e. the presence of a PV effect in BFO2.

FIGS. 3A, 3B and 3C depict the zero-bias photocurrent density as a function of time with green light (˜=532 nm) (FIG. 3A) or red light (˜=650 nm) (FIG. 3B) on or off, shining on the different sides of an exemplary photovoltaic device including BFO2 302 and an Au electrode 304 (a sketch is shown in the inset 300). The total light power was <3 mW, and the short-circuit photocurrent was measured for every 100 ms. The current with the light off decreased to <−0.1 picoA. Either-side illumination results in the same-direction zero-bias photocurrent, unambiguously demonstrating the photovoltaic effect in ferroelectric BFO. The large difference in the magnitude of photocurrent between green and red light illumination indicates that photo-excited carriers across bulk optical gap (N2.5 eV) dominate the photovoltaic effect. The observed R/L asymmetry may result from a thermoelectric power effect and/or uncontrolled asymmetries in the experimental configuration. For the first 60 minutes, the left electrode was illuminated and then the right electrode was illuminated for the next 60 minutes.

In principle, thermal variation induced by visible light illumination can contribute to the photocurrent increase in FIG. 1B. However, the simple decrease of resistance with temperature raised by light illumination certainly cannot cause the observed negative steady photocurrent for zero bias. On the other hand, a pyroelectric current can be generated by the change of the magnitude of ferroelectric polarization due to the temperature increase by light illumination. However, this is a transient effect occurring while the temperature change of a specimen is underway, and no steady-state photocurrent is expected from the pyroelectric effect. Thus, while the initial small spikes of photocurrent in FIG. 3 can be attributed to the pyroelectric current, the steady-state photocurrent in FIG. 3 has a different origin. Consistently, when the light was switched on, the photocurrent increased suddenly to a transient maximum before reaching a steady state. The transient component with green (red) light was −6% (−25%) of the steady-state photocurrent, and the time constant associated with the transient component was ˜15 (−60) seconds. The steady-state photocurrent density was −7.35 ¢tA/cm² under green light illumination on the left side. This value is much larger than the 2.6 nA/cm² observed under red light illumination, indicating that the photo-excited charge carriers across the bulk optical gap of ˜2.5 eV contributed to the PV effect in BFO. Also, since the BFO crystals were rather conducting, an equilibrium temperature gradient generated by continuous light illumination on one side of BFO may produce a steady current due to thermoelectric power voltage, although this effect should have produced an opposite-direction current when light illumination direction was changed from one side to the other side of the BFO crystal. The zero-bias photocurrent direction was always fixed, independent from the light illumination conditions, which is inconsistent with the thermoelectric power scenario. On the other hand, the thermoelectric power effect may contribute to the asymmetry in the magnitude of the photocurrent with different-side light illumination, which tumed out to be rather significant in BFO2. Obviously, any uncontrolled asymmetry in the electrode configuration or light illumination conditions may also contribute to the L-R asymmetry in the magnitude of photocurrent.

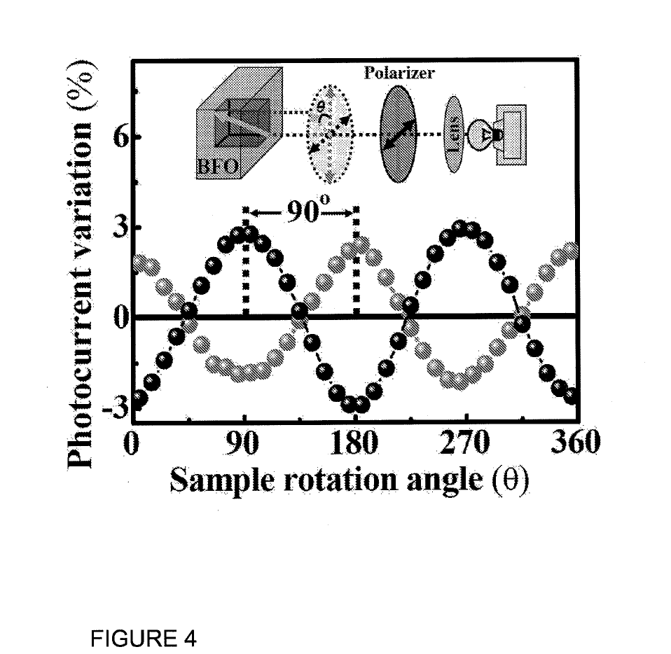

FIG. 4 depicts the variation of photocurrent with sample rotation under illumination with a linearly-polarized light, in accordance with an embodiment of the present invention. The experimental sketch is shown in the inset. The photovoltaic effect becomes maximum (minimum) when the polarized-light electric field is parallel (perpendicular) to the in-plane component of the ferroelectric polarization. A linear polarizer was placed between the light source and BFO2 to measure the effect of light polarization on the PV effect, as depicted in the inset in FIG. 4. The angle 0 between the in-plane component of ferroelctric polarization, determined by in-plane PFM, and the electric field vector of linearly polarized light was varied by 360°. The change of the photocurrent at zero bias with 0, shown in FIG. 4 with blue circles, followed closely a sinusoidal form with the periodicity of 180°. The maximum of photocurrent was observed when the polarized light electric field was along the in-plane ferroelectric polarization, and the current was minimal when the light electric field was perpendicular to the in-plane ferroelectric polarization. After the initial rotation experiment, the polarizer was rotated by 90°, and lighting conditions were readjusted for an optimum photocurrent. The change of photocurrent (green circles) with 0 after this polarizer rotation was similar to the one before rotating the polarizer, except for a 90° phase shift of 0. This demonstrated that the reproducible angular dependence is not due to any artifact of the optical set-up.

The above observations shed light on the origin of the PV effect in BFO. The sinusoidal behavior of the photocurrent at zero bias observed in the polarized-light rotation experiment was consistent with a non-linear optical effect scenario (13). When a ferroelectric is under light illumination, the 2^{nd} order optical response combined with a linear effect may give rise to an asymmetric induced polarization that may result in a DC rectification-like effect such as a PV effect. This effect is supposed to be maximal when the polarized-light electric field is along the ferroelectric polarization, and follows a sinusoidal angular dependence. This 2^{nd} order optical response is an intrinsic bulk effect, and therefore it should not be sample-dependent. However, a noticeable variation of the magnitude of the rectification and PV effects in different samples was observed, suggesting importance of impurities and defects for the transport mechanism. The space charge limited conduction suggested in the diode behavior was also consistent with the importance of impurities and defects. Any polarization-related asymmetry of impurity potentials may render the photocurrent sensitive to the orientation of light polarization, likely in a sinusoidal manner. Simple polarization-dependent band bending at the metal-BFO interfaces probably did not produce the observed directional dependence. In addition, little difference was found between Ag and Au electrodes on the diode effect, suggesting no major contribution from the band bending at the metal-BFO interfaces. On the other hand, the contribution of impurities/defects coupled with the band bending or the 2^{nd} order optical response to photocurrent may be influenced by the orientation of polarization. Impurities and defects are essential for DC electric conduction and optical excitations. Thus, the importance of the contribution of impurities/defects to the diode and PV effects appears to be rather evident.

In summary, the discovery of switchable diode and also photovoltaic effects in BFO revealed an intriguing charge conduction nature in leaky ferroelectrics. These results support the present invention's design of new memory devices using the switchable diode effect, and solar energy harvesting—photovoltaic cells—utilizing the PV effect.

Materials and Methods Used

Materials: Single crystals of BiFeO3 (BFO) were grown using a Bi2O3/Fe2O3/B2O3 flux by cooling slowly from 870 to 620° C. Plate-like crystals with a few mm2-area natural facets normal to a principal axis of pseudocubic cell were obtained. The growth temperature range was chosen in a way that it is near or below ferroelectric Tc, which may lead to a single ferroelectric domain structure in each single crystal. Indeed, comprehensive investigation of the single crystals with piezoresponse force microscopy (PFM), polarized optical microscopy and neutron scattering confirmed that each single crystal consists of a single ferroelectric domain. For electrical measurements, Ag or Au electrodes on both sides of BiFeO3 surfaces were deposited with shadow masks by using magnetron sputtering.

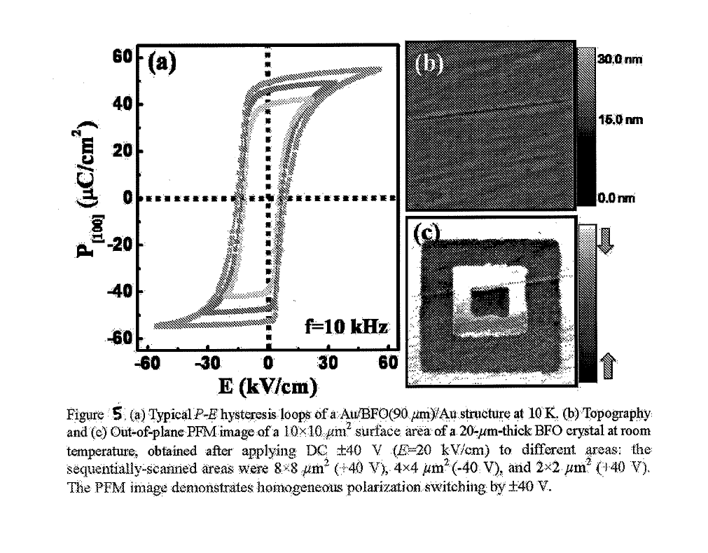

Ferroelectric characterization: The ferroelectric polarization-electric field (P-E) loops of BFO crystals were obtained using a Radiant Technology precision workstation with a virtual ground method. In order to obtain the precise electric polarization, precluding leakage current effect, switching current was measured at low temperatures and high frequencies. Typical P-E loops at 10 kHz, shown in FIG. 5A, were measured on a 90-Arm-thick BFO crystal sandwiched with Au electrodes at 10 K. The square-shape loops clearly confirm the presence of intrinsic ferroelectricity. With the maximum electric field of 55 kV/cm, the remnant polarization of −50/zC/cm² along the [100] direction was observed with a coercive field of 15 kV/cm. This corresponds to Pt1˜l˜=Pilool/COS(54.7°)=−86 pC/cm², consistent with a theoretical estimate.

Piezoresponse force microscopy (PFM): In order to verify switching of ferroelectric polarization with external electric fields, a piezoresponse force microscope was employed, consisting of a commercial scanning probe microscope (Veeco, Multimode) and a lock-in amplifier (Stanford Research System, SR830). A Pt/Cr-coated Si cantilever, tip radius of −25 rim, force constant of −40 N/m, and resonant frequency of −300 kHz, was used as a movable top electrode. DC voltage for polarization (domain) switching was applied to the bottom electrode, while the tip was grounded. BFO crystal was mechanically polished to as thin as 20/˜m to apply a sufficiently-large DC voltage to switch polarization. PFM domain images were obtained by detecting local (in-plane or out-of-plane) electromechanical vibration of BFO—i.e., displacement of the BFO surface originating from the converse piezoelectric effect—induced by external AC voltage with a lock-in technique. The amplitude and frequency of AC voltage were 1 Vrms and 17 kHz, respectively. FIG. 5B shows the topography of a polished BFO surface over a 10×10 ktm² area. FIG. 5C shows an out-of-plane PFM image of the same area obtained by applying DC +40 V (E=20 kV/cm) to the Au bottom electrode with three consecutive scans. The scanned areas were 8×8/˜m² (+40 V), 4×4/tm2 (−40 V), and 2×2/zm⁻(+40 V), in sequence. The dark region in FIG. 5C represents the area with an upward component of polarization vector induced by +40 V, while the area with a downward component of polarization vector induced by −40 V appears bright. Domain regions were well defined, i.e., each region produced a uniform piezoresponse, indicating a homogeneous polarization state. The magnitudes of the piezoresponse signals of the bright domains (virgin or polarized by −40 V) and the dark domains (polarized by +40 V) were similar, suggesting a single polarization switching. Therefore, the PFM image shows clear evidence of ferroelectric polarization switching of a BFO single crystal at room temperature.

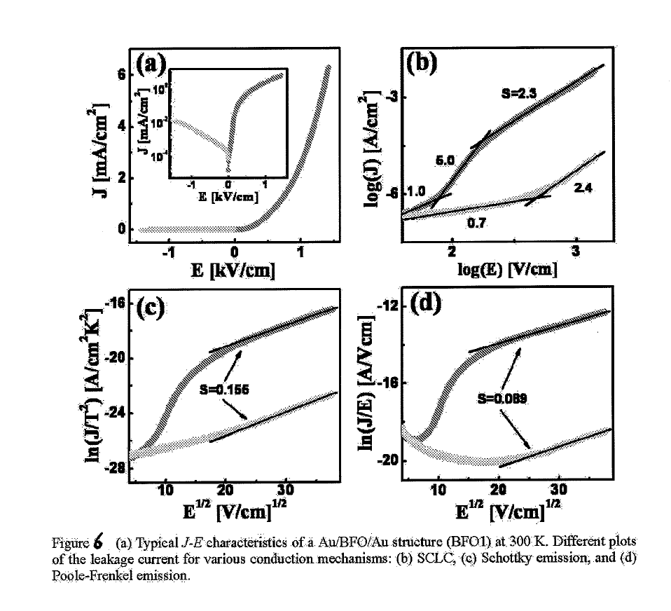

Electronic conduction mechanism: In order to understand electronic transport mechanism in BFO, the detailed E dependence of current density, ˜/, of BFO1 with symmetric Au electrodes (in the dark) was investigated. The ˜/(E) measurements were performed with a Keithley 2400 multimeter and a Quantum Design physical properties measurement system (PPMS). FIGS. 6A, 6B, 6C and 6D show the ˜/(E) curve of a symmetric Au/BFO1/Au structure at 300 K; linear-scale in FIG. 6a and long-scale in the inset of FIG. 6A. Note that the applied E fields were much less than the coercive field (about 15 kV/cm) for electric polarization, so polarization switching does not occur during the E sweep for ˜/(E). The E dependence was highly non-linear, and there exists a significant asymmetry with respect to the polarity of E, indicating the presence of a diode-like effect. The rectification ratio at ±1.4 kV/cm was >4×102. This asymmetric electronic transport nature with symmetric electrodes indicates that the observed rectifying behavior is governed by the bulk characteristics of BFO. As discussed herein, this rectification direction switched when electric polarization was flipped by large external voltage pulses, proving that the diode effect is associated with the bulk properties of BFO. The possible conduction mechanisms in ferroelectric perovskite oxides such as BiFeO3 include the interface-limited Schottky emission, space-charge-limited bulk conduction (SCLC) and bulk-limited Poole-Frenkel emission (PF). Schottky and PF emissions can be examined from the linear behaviors in In(˜//T^{z}) vs E°⁵ and In(J/E) vs E°⁵ plots, as shown in FIGS. 6c and 6d, respectively. These plots certainly exhibit linear regimes, and the magnitude of the linear slope is supposed to be ˜Cl/(T.˜/˜), where e is dielectric constant and T is temperature. It turns out that the z estimated form the slope is unphysically small, two-orders of magnitude smaller than the literature value of z˜:6.25 (7). Thus, it appears that Schottky or PF emission is not the dominant conduction route. On the other hand, the good power-law fits in the log(d) vs log(E) plot of FIG. 6b seem to indicate dominant SCLC mechanisms. As evident in FIG. 6b, three (two) distinct E regions with different slopes exist for the forward (reverse) bias. The slopes in the log plot were 1.0, 5.0, and 2.3 for the forward bias, and 0.7 and 2.4 for the reverse bias. These power-law relations are consistent with three types of conduction: Ohm's law (Joc El), trap-filled limited (˜/o˜Eⁿ with n >2), and trap-free space charge limited (˜/oc E2). Free carriers induced by shallow impurities and defects can be present in BFO, and can induce the Ohmic behavior in low E. For larger E, injected carrier density exceeds the free carrier density, and SCLC associated with deep trap centers becomes important. In the E region where only a part of deep traps become filled, the increase of current with increasing E is fast, resulting in the power law dependence with a power larger than 2. This is the so-called trap-filled limited region, and ionic defects such as oxygen vacancies can create the relevant deep-trap energy levels in the band gap. Further carrier injection fills all trap centers, and thus trap-free space charge limited conduction, SCLC, becomes dominant in high E, leading to a square-law characteristic (˜/ocE2: the so-called Child's law). The distinct intermediate region of trap-filled limited conduction is only observed in the forward bias, while the direct transition from Ohmic to SCLC regions without an intermediate region occurs in the reverse bias. These observations suggest that the contribution of deep trap centers to conduction depends strongly on the relative orientation between the internal field produced by space charge and ferroelectric polarization.

The increase of asymmetry in J(E) and rectification ratio with increasing temperature can be examined in term of SCLC. As discussed above, the J(E) asymmetry appears to be mainly due the presence of a trap-filled limited conduction region in the forward direction (positive bias region). The T dependence of these asymmetries may result from the T evolution of thermal excitations overan asymmetric trap potential.

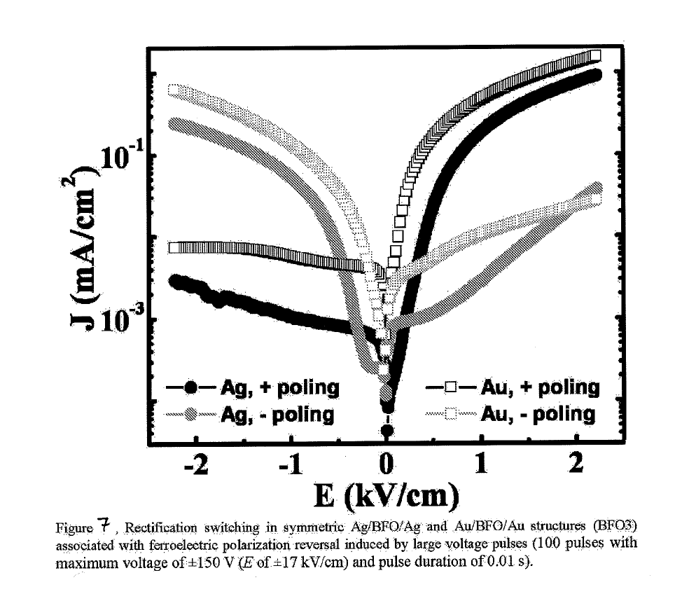

Rectification effect with various electrodes: As shown in FIG. 7, Au and Ag electrodes with a symmetric configuration on BFO3 produced a similar rectification effect, and in both cases, the rectification direction was switched by flipping electric polarization by electric pulses (100 pulses with maximum voltage of ±150 V and pulse duration of 0.01s). Although Au and Ag have different work functions (5.1 eV for Au and 4.26 eV for Ag), ˜/-E characteristics are almost identical, irrespective of the type of electrodes. All of these observations indicate that the diode effect stems primarily from the bulk characteristics of BFO, rather than a simple interfacial effect.

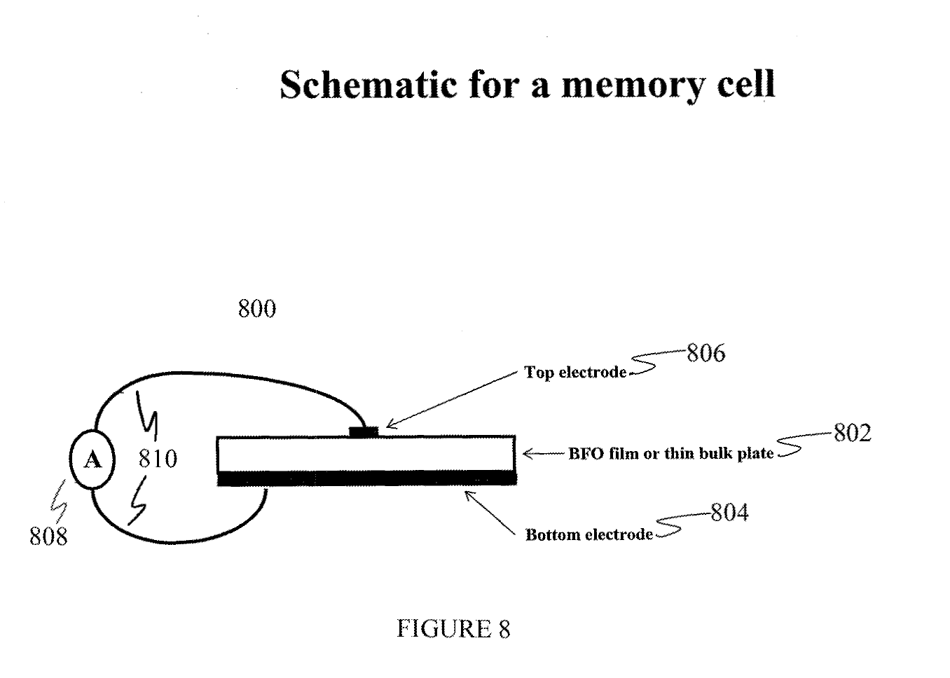

FIG. 8 is a schematic diagram depicting an exemplary memory cell 800. In accordance with an embodiment of the present invention, the BFO film or thin bulk plate 802 is sandwiched between a bottom electrode 804 and a top electrode 806. The top and bottom electrodes 806, 804 are then optimally connected via conducting leads or traces 810 to circuit A 808. An array (not depicted) with a plurality of top electrodes can be used for non-volatile memories.

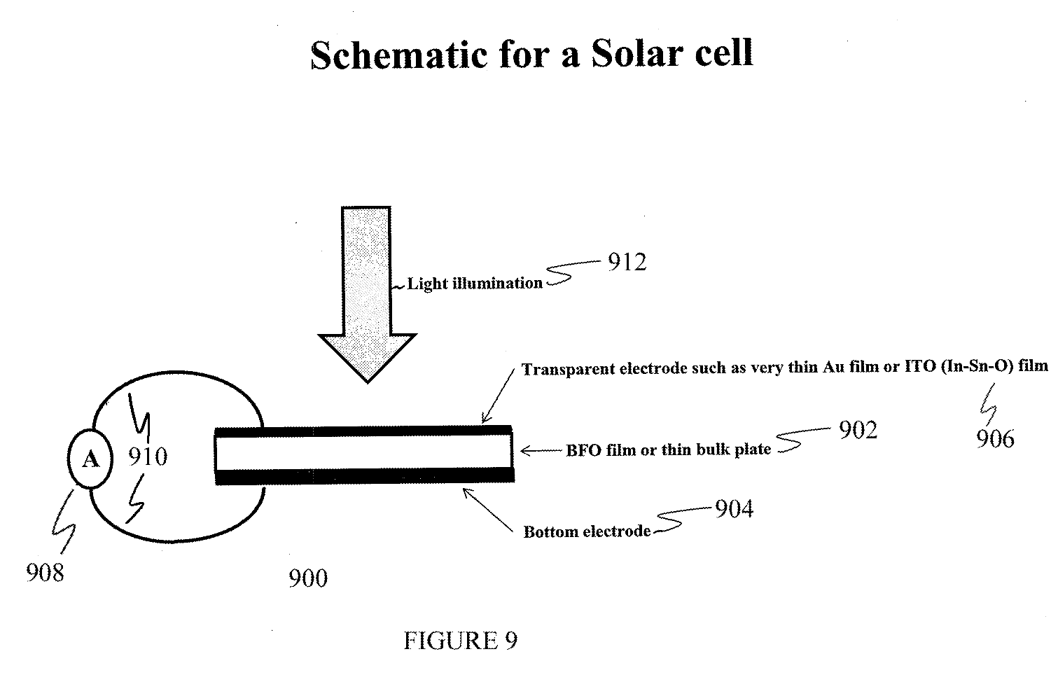

FIG. 9 is a schematic diagram depicting an exemplary solar cell 900. In accordance with an embodiment of the present invention, the BFO film or thin bulk plate 902 is sandwiched between a bottom electrode 904 and a top electrode 906. The top and bottom electrodes 906, 904 are then optimally connected via conducting leads or traces 910 to circuit A 908. Light illumination 912 drives the photovoltaic process as described hereinabove.

An embodiment of the present invention provides a diode including a single-crystalline ferroelectric having remnant electrical polarization sandwiched with semitransparent electrodes.

In a preferred embodiment of the invention, the single-crystalline ferroelectric is BiFeO₃ (“BFO”). In various embodiments of the invention, the BFO has a thickness ranging from 70 ma-90 ma, and the electrodes are Au or Ag.

In a further embodiment of the invention, the a plurality of the above diodes are operatively connected to form an electronic memory network of an electronic memory device.

Another embodiment of the present invention provides a photovoltaic device including a single-crystalline ferroelectric having remnant electrical polarization sandwiched with semitransparent electrodes.

A further embodiment of the invention provides a solar cell which includes a plurality of the above photovoltaic device, the photovoltaic devices being interconnected either serially or in parallel.

The following references are herein incorporated by reference in their entirety for all purposes:

1. J. F. Scott, Ferroelectric Memories (Springer, Heidelberg, 2000).

2. M. Dawber, K. M. Rabe, J. F. Scott, Rev. Mod. Phys. 77, 1083 (2005).

3. J. F. Scott, J. Phys.: Condens. Matter21), 021001 (2008).

4. J. Wang etal., Science 299, 1719 (2003).

5. V. M. Fridkin, B. N. Popov, Sov. Phys. Usp. 21,981 (1978).

6. A. M. Glass, D. Von der Linde, T. J. Negran, Appl. Phys. Lett. 25, 233 (1974).

7. N. Noginova et al., J. Opt. Soc. Am. B 14, 1390 (1997).

8. G. Dalba, Y. Soldo, F. Rocca, V. M. Fridkin, Ph. Sainctavit, Phys. Rev. Lett. 74, 988 (1995).

9. Y. S. Yang et al., AppL Phys. Lett. 76, 774 (2000).

10. P. Poosanaas, A. Dogan, S. Thakoor, K. Uchino, J. Appl. Phys. 84, 1508 (1998).

11. L. Pintilie, I. Vrejoiu, G. L. Rhun, M. Alexe, J. AppL Phys. 11)1, 064109 (2007).

12. V. I. Belinicher, B. I. Sturman, Sov. Phys. Usp. 23, 199 (1980).

13. K. Tonooka, P. Poosanaas, K. Uchino, Proc. SPIE 3324, 224 (1998).

14. A. J. Hauser et al., Appl. Phys. Lett. 92, 222901 (2008).

15. S. R. Basu etal., AppL Phys. Lett. 92, 091905 (2008).

16. S. Lee, W. Ratcliff II, S-W. Cheong, V. Kiryukhin, Appl. Phys. Lett. 92, 192906 (2008).

17. S. Lee etal., Phys. Rev. B78, 100101 (2008).

18. Y. W. Xie etaL, J. Phys.: Condens. Matter 19, 196223 (2007).

19. F. Gao et aL, Appl. Phys. Lett. 89, 102506 (2006).

20. S. Lee, W. Ratcliffll, S-W. Cheong, and V. Kiryukhin, AppL Phys. Lett. 92, 192906 (2008).

21. S. Lee, T. Choi, W. Ratcliffll, R. Erwin, S-W. Cheong, and V. Kiryukhin, Phys. Rev. B 78, 100101 (2008).

22. J. B. Neaton, C. Ederer, U. V. Waghmare, N. A. Spaldin, and K. M. Rabe, Phys. Rev. B 71, 014113 (2005).

23. V. Nagarajan, et al., AppL Phys. Lett. 81, 4215 (2002).

24. See, for example, M. Dawber, K. M. Rabe, and J. F. Scott, Rev. Mod. Phys. 77, 1083 (2005).

25. See, for example, M. A. Lampert and P. Mark, Current injection in solids (Academic press, New York, 1970).

26. H. Yang et al., Appl. Phys. Lett. 91, 072911 (2007).

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A diode comprising a single-crystalline ferroelectric having remnant electrical polarization sandwiched with semitransparent electrodes.

2. The diode according to claim 1, wherein the single-crystalline ferroelectric comprises BiFeO₃ (“BFO”).

3. The diode according to claim 2, wherein the single-crystalline ferroelectric BFO is ˜70 ma thick.

4. The diode according to claim 2, wherein the single-crystalline ferroelectric BFO is ˜80 ma thick.

5. The diode according to claim 2, wherein the single-crystalline ferroelectric BFO is ˜90 ma thick.

6. The diode according to clam 2, wherein the electrodes comprise Au or Ag.

7. An electronic memory device comprising:
a plurality of single-crystalline ferroelectric diodes having remnant electrical polarization sandwiched with semitransparent electrodes;
the plurality of diodes operatively connected in an electronic memory network.

8. A photovoltaic device comprising a single-crystalline ferroelectric having remnant electrical polarization sandwiched with semitransparent electrodes.

9. The photovoltaic device according to claim 8, wherein the single-crystalline ferroelectric comprises BiFeO₃ (“BFO”).

10. The photovoltaic device according to claim 9, wherein the single-crystalline ferroelectric BFO is ˜70 ma thick.

11. The photovoltaic device according to claim 9, wherein the single-crystalline ferroelectric BFO is ˜80 ma thick.

12. The photovoltaic device according to claim 9, wherein the single-crystalline ferroelectric BFO is ˜90 ma thick.

13. The photovoltaic device according to claim 9, wherein the electrodes comprise Au or Ag.

14. A solar cell comprising a plurality of photovoltaic devices, each photovoltaic device comprising a single-crystalline ferroelectric having remnant electrical polarization sandwiched with semitransparent electrodes, the plurality of photovoltaic devices being interconnected serially.

15. A solar cell comprising a plurality of photovoltaic devices, each photovoltaic device comprising a single-crystalline ferroelectric having remnant electrical polarization sandwiched with semitransparent electrodes, the plurality of photovoltaic devices being interconnected in parallel.
